(19) United States
(12) Patent Application Publication
(10) Pub. No.: US 2005/0179483 A1
(43) Pub. Date: Aug. 18, 2005

(54) High-voltage transistors on insulator substrates

(76) Inventors: Chriswell G. Hutchens, Stillwater, OK (US); Roger L. Schultz, Aubrey, TX (US); Narendra Babu Kayathi, Stillwater, OK (US)

Correspondence Address: BAKER BOTTS, LLP, 910 LOUISIANA, HOUSTON, TX, 77002-4995, US

(21) Appl. No.: 10/992,406

(22) Filed: Nov. 18, 2004

Related U.S. Application Data
(60) Provisional application No. 60/523,124, filed on Nov. 18, 2003.
(60) Provisional application No. 60/523,122, filed on Nov. 18, 2003.
(60) Provisional application No. 60/523,121, filed on Nov. 18, 2003.

(51) Int. Cl. H03K 17/615

(52) U.S. Cl. 327/483

(57) ABSTRACT

High-voltage transistors, charge pumps, voltage level shifters, and method for fabricating the same are disclosed. The high-voltage transistor includes a substrate that includes sapphire or diamond and an active layer disposed on the substrate. The active layer includes a drain region, a source region, a channel region, and a lightly-doped drain region between the channel region and the drain region.

### CROSS-REFERENCE TO RELATED APPLICATION

This application claims priority to commonly owned U.S. provisional patent application Ser. No. 60/523,124, filed Nov. 18, 2003, entitled “High-Temperature Magnetic Random Access Memory,” by Roger Schultz, Chris Hutchens, James J. Freeman, and Chia Ming Liu. This application claims priority to commonly owned U.S. provisional patent application Ser. No. 60/523,122, filed Nov. 18, 2003, entitled “Cell Library for VHDL Automation,” by Chris Hutchens and Roger Schultz. This application claims priority to commonly owned U.S. provisional patent application Ser. No. 60/523,121, filed Nov. 18, 2003, entitled “SOS Charge Pump,” by Chris Hutchens and Roger L. Schultz.

### BACKGROUND

As activities conducted in high-temperature environments, such as well drilling, become increasingly complex, the importance of including electronic circuits for activities conducted in high-temperature environments increases.

Semiconductor based components, including Complementary Metal Oxide Semiconductor (CMOS) devices, may exhibit increased leakage currents at high temperatures. For example, conventional bulk-silicon CMOS devices may exhibit increased leakage currents, and hence decreased resistances, in response to an increase in the environmental temperature of the device.

### BRIEF DESCRIPTION OF THE DRAWINGS

FIGS. 1-2 are flow charts of a system for producing transistors.

FIGS. 3-9 are block diagrams of transistors in stages of fabrication.

FIGS. 10-13 are schematic diagrams of charge pumps.

FIGS. 14A and 14B are schematic diagrams of a voltage level shifter.

### DETAILED DESCRIPTION

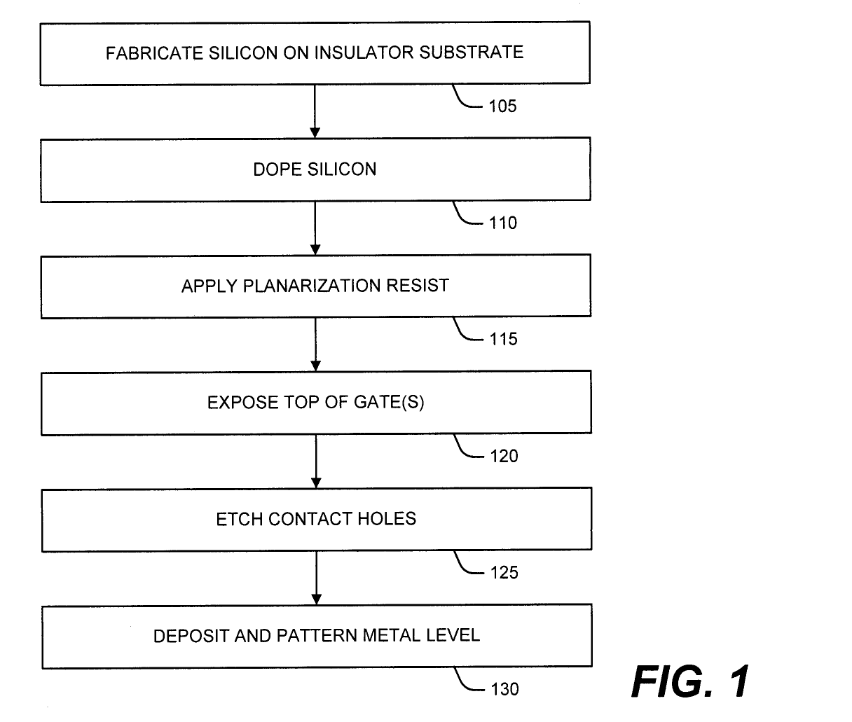

FIG. 1 shows an example system for fabricating one or transistors is shown in FIG. 1. Although the example system shown in FIG. 1 is for fabricating a transistor, it may be generalized to fabricate other devices on the substrate. The system may fabricate a silicon layer on the insulator substrate (block 105). The system may dope the silicon to create one or more p regions and one or more n regions (block 110). The system may apply a planarization resist to one or more portion of the device (block 115). The system may planarize the device to expose the top of one or more gates in the device (block 120). The system may etch more or more contact holes to connect one or more portions of the device to a metal layer (block 125). The system may deposit and pattern the metal layer (block 130).

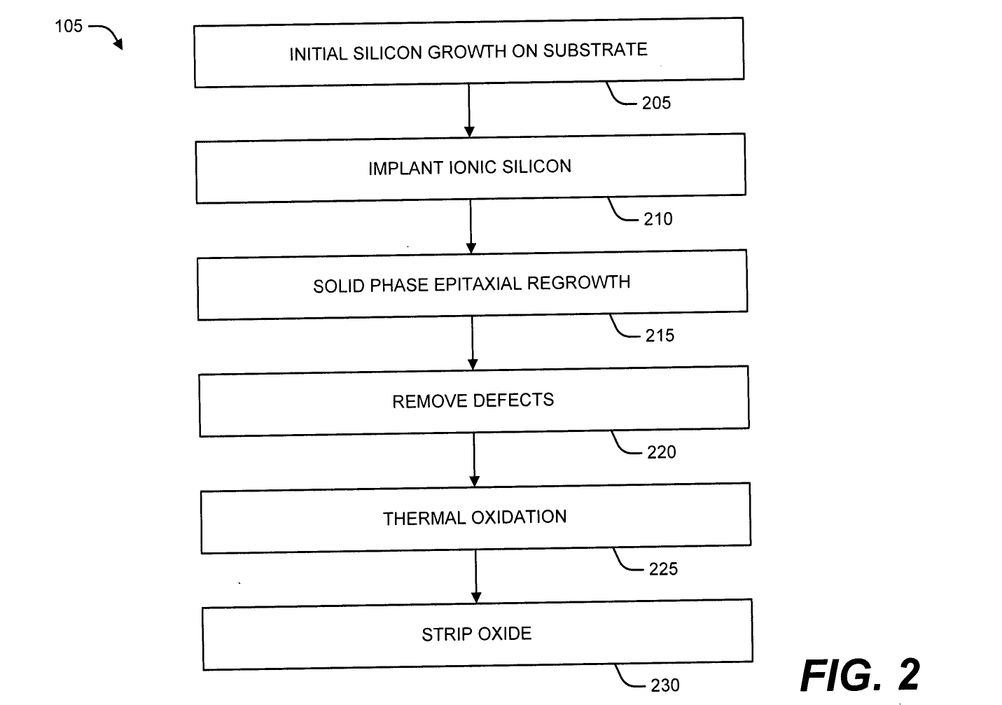

An example system for fabricating a silicon layer on an insulator substrate (block 105) is shown in FIG. 2. The example system shown in FIG. 24 may create a thin-film layer of silicon on the insulator substrate. The system may perform an initial silicon grown on the substrate (block 205). This initial growth may be performed by chemical vapor deposition. The system may implant an ionic silicon layer (e.g., positively charged) on the initial silicon layer (block 210). The system may anneal the silicon layer by facilitating a solid phase epitaxial regrowth (block 215). This process may be performed at an elevated temperature, for example at a temperature of about 550° C. The system may also anneal the silicon layer by removing defects (block 220). This removal of defects may also be performed at an elevated temperature, for example at a temperature of about 900° C. The system may cause the silicon layer to undergo thermal oxidation to form an oxide layer (e.g., SiO₂) on the silicon layer (block 225). The system may then strip some or all of the oxide layer from the silicon layer (block 230). In some example systems a layer of oxide is left on the silicon layer.

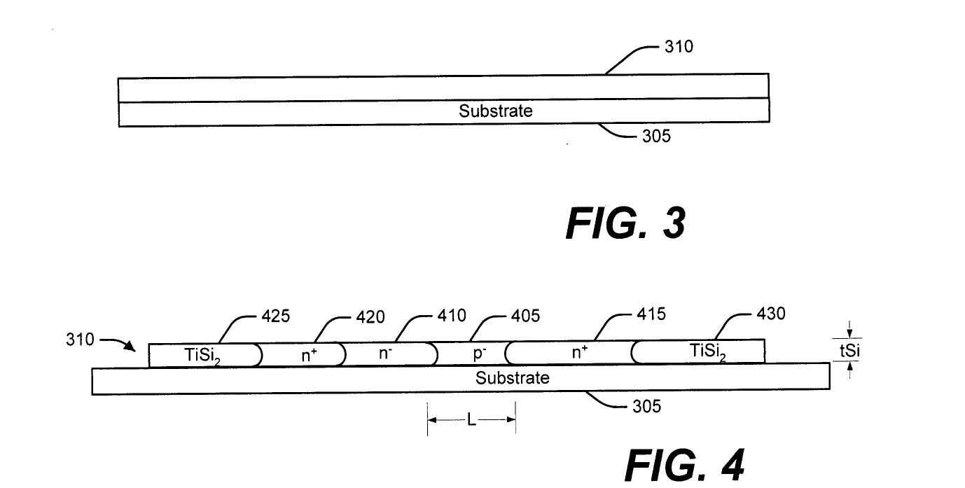

FIGS. 3-9 show an example device (e.g., a transistor) in phases of fabrication according to the system shown in FIG. 17. FIG. 3 shows the example device after the silicon layer 310 is fabricated on the insulator substrate 305. The insulator substrate 305 may exhibit a high resistance at an elevated temperature. Example substrates may include diamond and sapphire. Because of the high resistance of the insulator substrate 305 at elevated temperatures, devices fabricated on the insulator substrate 305 may exhibit lower leakage currents at elevated temperatures than devices fabricated on substrates with low resistance at elevated temperatures.

FIG. 4 shows the example device after one or more regions of the silicon layer 310 are doped (FIG. 1, block 110). The silicon layer 310 may include one or more p-regions, such as p-region 415. The silicon layer 310 may include one or more n-regions, such as n-regions 410, 420, and 415. Some of the doped regions in the silicon layer 310 may be doped more heavily than other regions. For example, n-regions 420 and 415 are doped more heavily than n region 410 and p-region 405. In some example systems where n region 415 is the drain of the transistor, the lighter-doped n-region 410 may be referred to as a lightly-doped drain (LDD). The extended LDD in the transistor may allow it to handle higher voltage levels before encountering an avalanche condition. In general, as used herein, the term “high-voltage transistor” refers to a transistor that includes an LDD region or other structures or features to increase the avalanche threshold of the transistor.

The example doping of the silicon layer 310 shown in FIG. 4 creates a p-channel or NMOS transistor. The doped silicon layer 310 may be referred to as an active layer. Semiconductor devices, such as the transistor shown in FIG. 4 may be characterized by a channel length L. The devices may also be characterized by a thickness of the active layer tSi. In some example systems, device characteristics, such as L and tSi may be altered to change the thermal behavior of the device.

The silicon layer may include one or more silicide regions such as TiSi₂ regions 425 and 430. The silicon layer may be etched away outside silicide regions 425 and 430. In some example systems, the silicide regions 425 and 430 may be formed on or partially within doped regions such as n-regions 415 and 420.

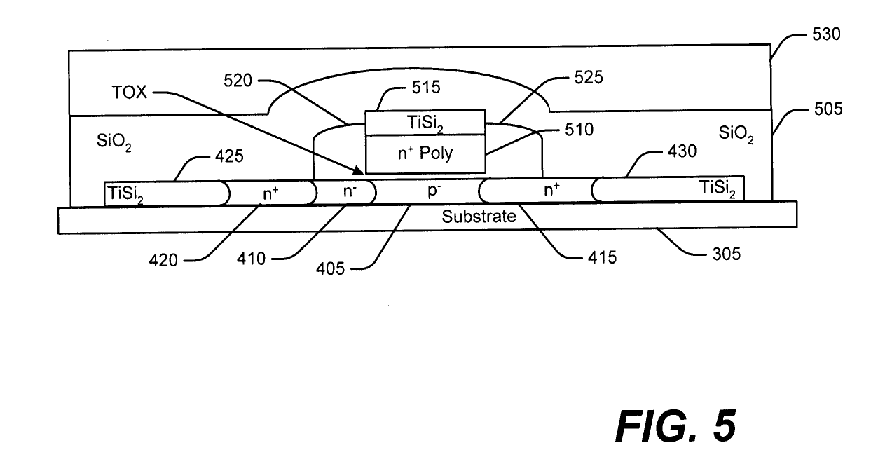

FIG. 5 shows the example device after additional semiconductor layers are formed and a planarization resist is applied to the device (FIG. 1, block 115). An oxide layer, such as SiO₂ layer 505 may be applied to the device. One or more poly layers such as the n-poly layer 510 may be fabricated on the device. The poly layer 510 may be separated from the active layer by a distance TOX. The thickness of TOX may be controlled to change the behavior of the device. One or more silicide layers, such as TiSi₂ layer 515 may be fabricated on the device. The oxide layer 505 may include one or more sidewalls such as SiO₂ sidewalls 520 and 525. The sidewalls 525 and 530 may be referred to as oxide spacers. A planarization resist 530 may be spun onto the device.

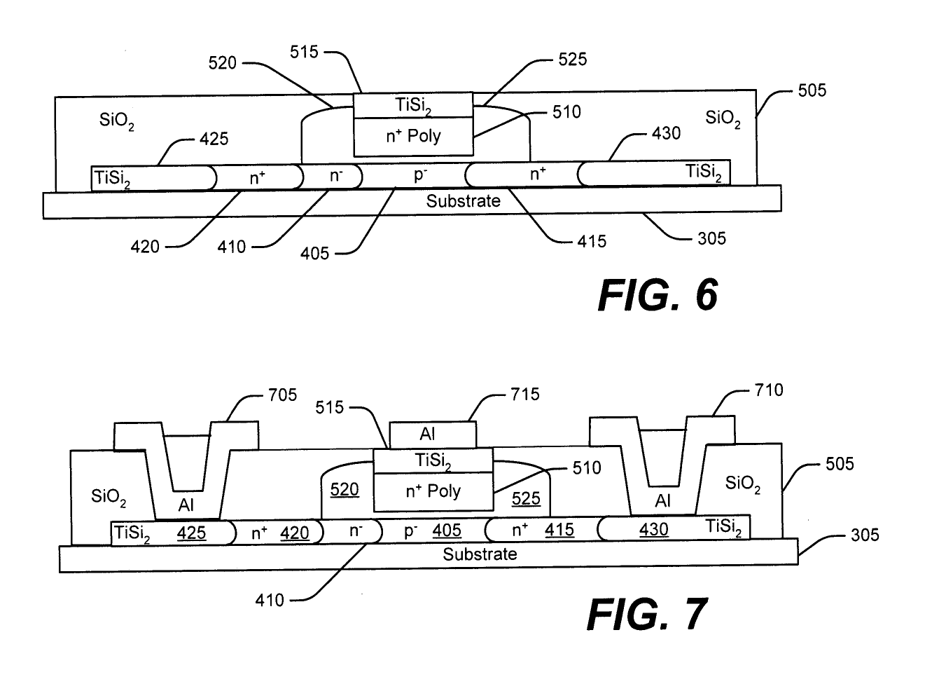

FIG. 6 shows the example device after planarization (FIG. 1, block 120). The planarization may expose one or more gates, such as the top of TiSi₂ layer 515. FIG. 7 shows the example device after one or more contact holes are etched (block 125) and a metal layer is deposited and patterned (block 130). In the example system, contact holes may be etched so that metal layers 705 and 710 may contact TiSi₂ regions 425 and 430, respectively. A metal layer 715 may also be deposited and patterned to contact TiSi₂ layer 425. The metal layers may include one or more conductive materials. For example the metal layers 705, 710, and 715 may include aluminum.

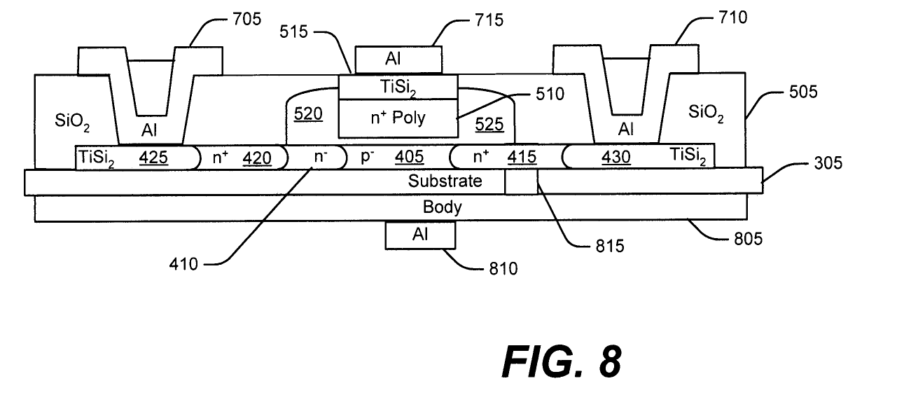

Another example high-voltage transistor is shown in FIG. 8. The body 805 of the transistor is shown. The device may include a metal contact 810 to the body 805. The device may also include a body tie 815 to connect the source (n region 415) to the body 805. In other example systems, the body 805 may not be tied to anything. In this situation, the device is said to have a “floating body.”

As discussed above one or more properties of the high-voltage transistors may be adjusted to alter the behavior of the device. The example system adjusts the length of the active layer (L) and the thickness of the substrate (tsi), so that L/tSi is in a predetermined range. In one example device, the predetermined range may be above 4. In other example devices, the predetermined range may be above 5, 6, or 7. In one example system the predetermined range may be between 7 and 30. In another example system the predetermined range may be from 11.8 to 25. In another example system L/tSi may be about 17.7. The example system may also adjust the length of the LDD region 410. In some example systems the dimensions of the LDD region may be adjusted.

Another example system may alter two or more of tSi, TOX, L, or one or more other dimensions of the device to adjust other properties of the device such as switching speed or leakage current.

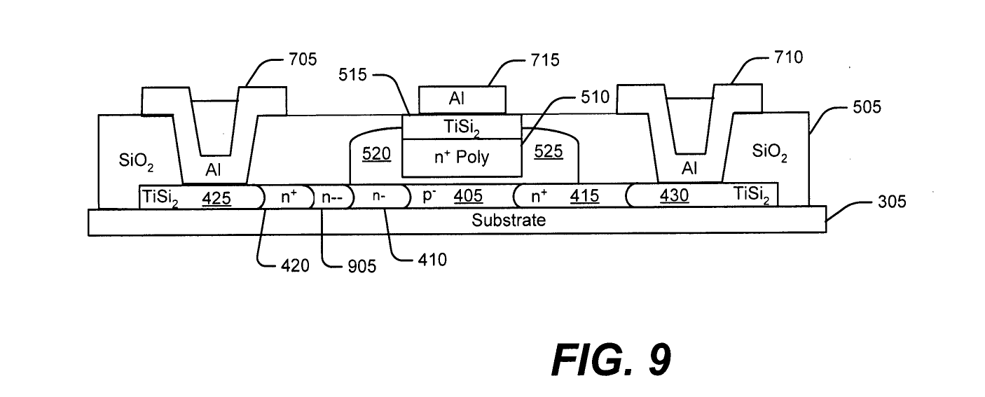

Another example high-voltage transistor is shown in FIG. 9. The active layer includes a resistive region 905 between the channel region (p-region 405) and the drain region (n-region 420). The resistive region 905 may be doped n−- or include another material with an increased resistance. In some implementations, the device may not include a LDD region 410 with the resistive region 905.

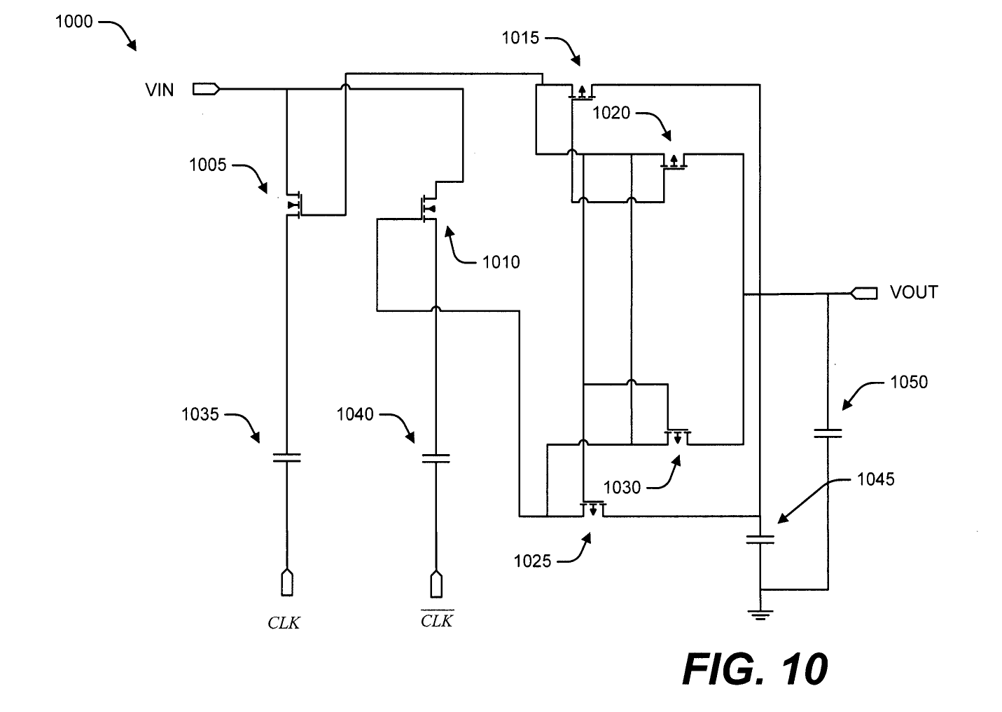

The high-voltage transistors illustrated above may be used to implement one or more circuits. For example, the high-voltage transistors may be used to implement a charge pump as shown generally at 1000 in FIG. 10. The charge pump shown in FIG. 10 may be referred to as a cross-coupled positive charge pump. It may include one or more high-voltage transistors such as high-voltage transistors 1005-1030. The charge pump may also include one or more capacitors such as capacitors 1035-1050, which may be coupled to one or more of the high-voltage transistors. In one example charge pump, transistors 1005, 1010, and 1015 may each have a length of about 2 μm and a width of about 3 μM. The transistors 1020, 1025, and 1030 may each have a length of about 2 μm and a width of about 6.4 μm. The capacitors 1035, 1040, 1045, and 1050 may have capacitances of about 1 pF, 1 pF, 100 fF, and 1.5 pF, respectively. The example charge pump may receive an input signal VIN and produce an output signal VOUT. The example charge pump may be clocked by a clock line CLK and an inverted clock line \overline{CLK}. In some example systems, the clock and inverted clock lines may be buffered.

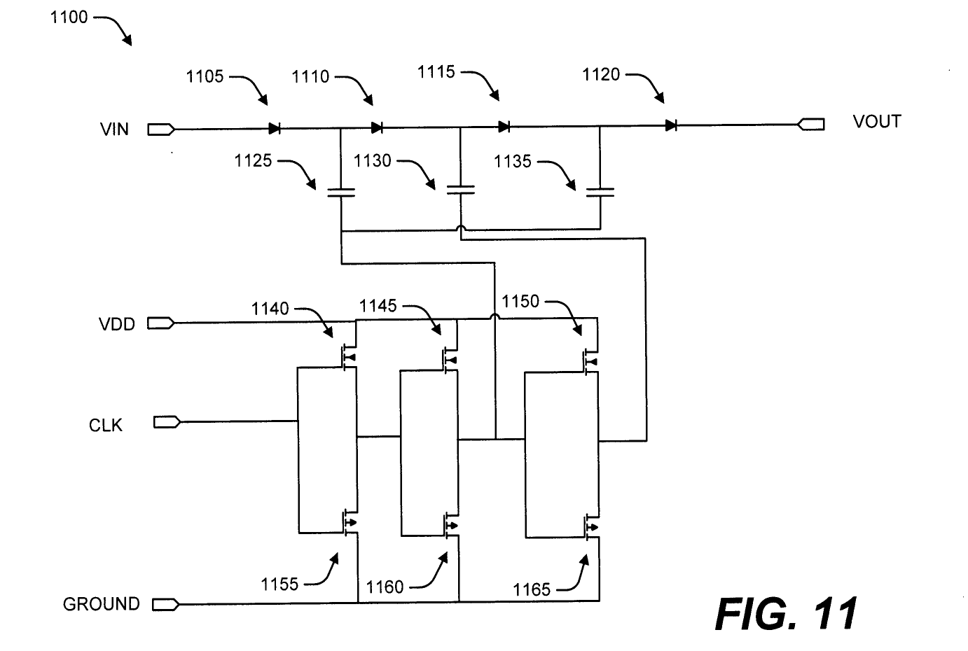

Another example charge pump is shown generally at 1100 in FIG. 11. The charge pump shown in FIG. 11 may be referred to as a positive diode charge pump. The charge pump 1100 may include one or more diodes, such as diodes 1105, 1110, 1115, and 1120. In one implementation, one or more of the diodes 1105, 1110, 1115, and 1120 may be GPPN diodes. The charge pump 1100 may also include one or more capacitors, such as capacitors 1125, 1130, and 1135, which may be coupled to the diodes 1105-1120. In one implementation the capacitors 1125, 1130, and 1135 may each have capacitances of about 1 pF. The charge pump 1100 may include on or more high-voltage transistors, such as high-voltage transistors 1140, 1145, 1150, 1155, 1160, and 1165. In one implementation, one or more of the high-voltage transistors may be implemented using one or more “fingers” or transistor units. In one implementation, each of the fingers may have a width of about 6 μm and a length of about 2 μm. In one example charge pump, transistors 1140, 1145, 1150, 1155, 1160, and 1165 may include 3, 3, 10, 10, 4, and 4 fingers, respectively. The charge pump 1100 may receive an input signal VIN and produce and output signal VOUT. The charge pump 1100 may receive a clock signal CLK.

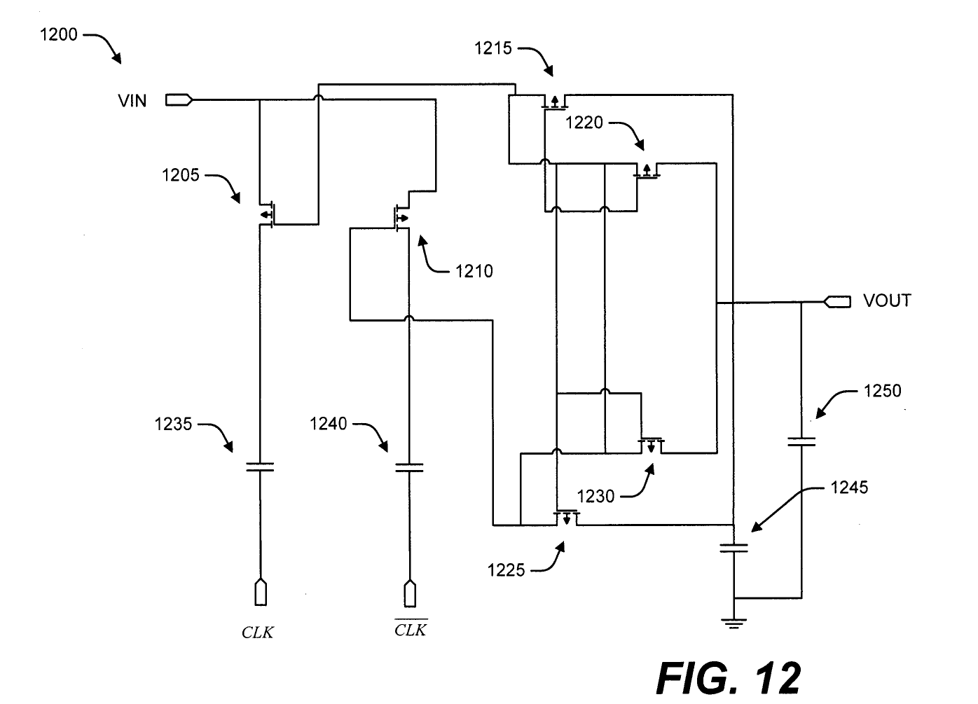

Another example charge pump is shown generally at 1200 in FIG. 12. The charge pump shown in FIG. 12 may be referred to as a cross-coupled negative charge pump. It may include one or more high-voltage transistors such as high-voltage transistors 1205-1230. The charge pump may also include one or more capacitors such as capacitors 1235-1250, which may be coupled to one or more of the high-voltage transistors. In one example charge pump, transistors 1205, 1210, and 1215 may each have a length of about 2 μm and a width of about 3 μm. The transistors 1220, 1225, and 1230 may each have a length of about 2 μm and a width of about 6.4 μm. The capacitors 1235, 1240, 1245, and 1250 may have capacitances of about 1 pF, 1 pF, 100 fF, and 1.5 pF, respectively. The example charge pump may receive an input signal VIN and produce an output signal VOUT. The example charge pump may be clocked by a clock line CLK and an inverted clock line \overline{CLK}. In some example systems, the clock and inverted clock lines may be buffered.

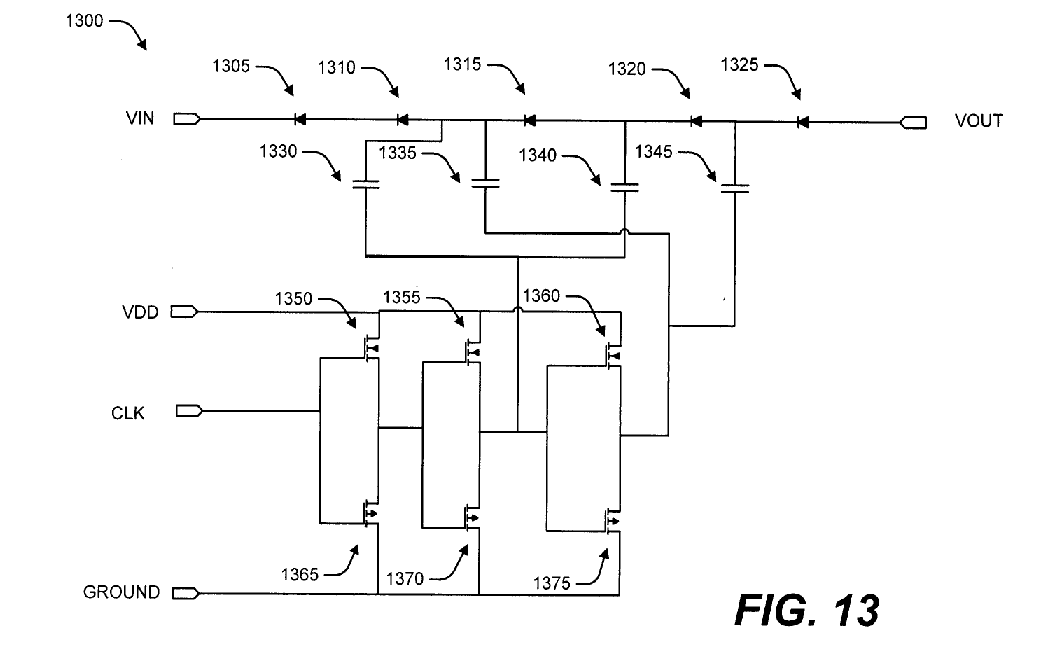

Another example charge pump is shown generally at 1300 in FIG. 13. The charge pump shown in FIG. 13 may be referred to as a negative diode charge pump. The charge pump 1300 may include one or more diodes, such as diodes 1305, 1310, 1315, 1320, and 1325. In one implementation, one or more of the diodes 1305, 1310, 1315, 1320, and 1325 may be GNNP diodes. The charge pump 1300 may also include one or more capacitors, such as capacitors 1330, 1335, 1340, and 1345, which may be coupled to the diodes 1305-1325. In one implementation the capacitors 1330, 1335, 1340, and 1345 may each have capacitances of about 1 pF. The charge pump 1300 may include on or more high-voltage transistors, such as high-voltage transistors 1350, 1355, 1360, 1365, 1370, and 1375. In one implementation, one or more of the high-voltage transistors may be implemented using one or more “fingers” or transistor units. In one implementation, each of the fingers may have a width of about 6 μm and a length of about 2 μm. In one example charge pump, transistors 1350, 1355, 1360, 1364, 1370, and 1375 may include 3, 3, 10, 10, 4, and 4 fingers, respectively. The charge pump 1300 may receive an input signal VIN and produce and output signal VOUT. The charge pump 1300 may receive a clock signal CLK.

Each of the example charge pumps 1000, 1100, 1200, and 1300 may be used as stages in a larger chare pump. In one implementation, the VOUT of one of the charge pumps may be connected as the VIN to another charge pump. In general, a charge pump may include one or more stages.

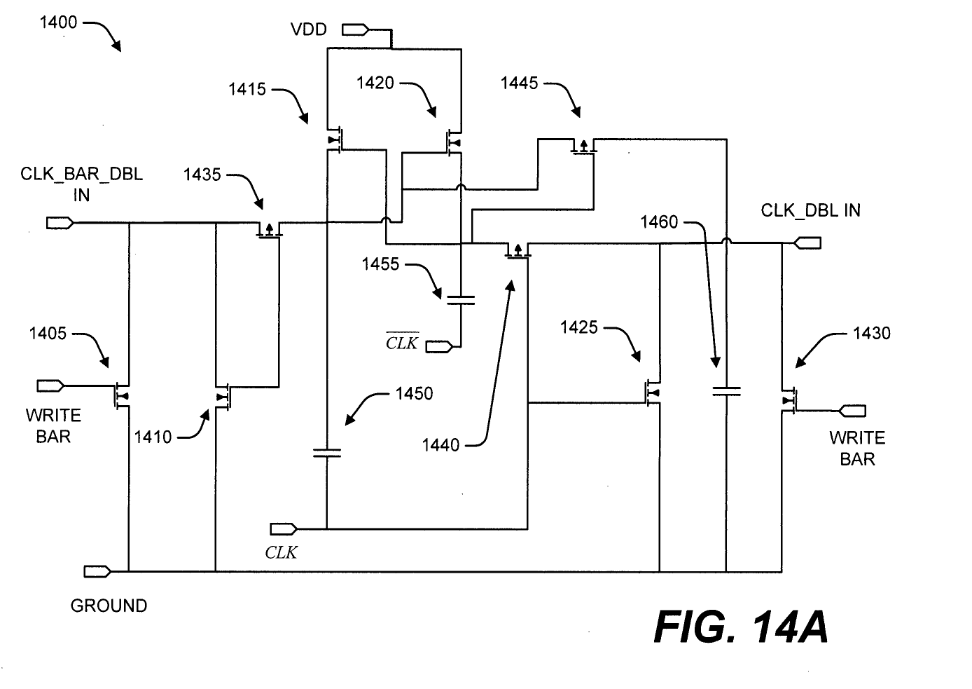

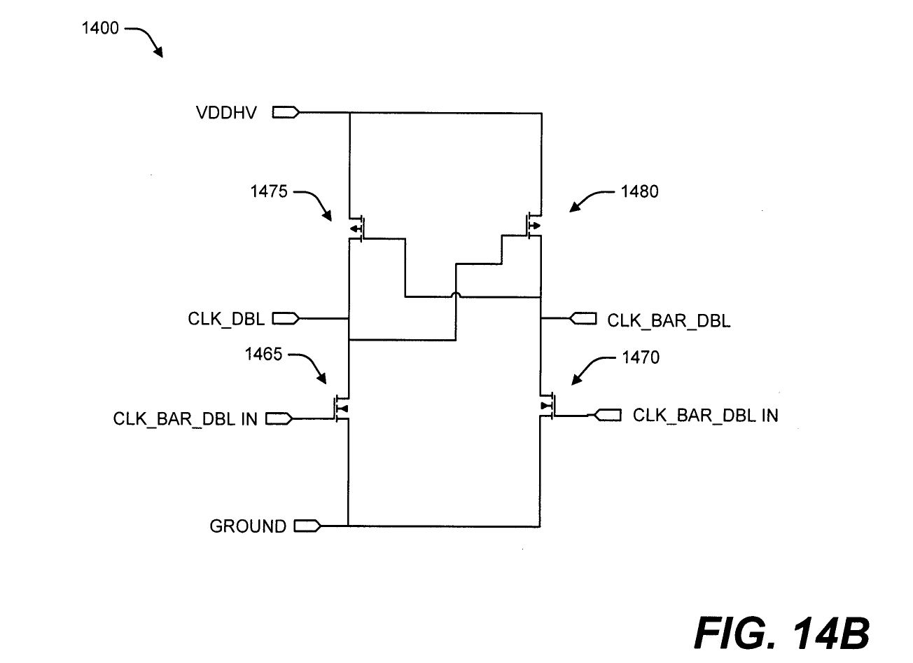

An example voltage-level shifter is shown generally at 1400 in FIGS. 14A and 14B. The portion of the voltage-level shifter 1400 shown in FIG. 14A includes NMOS transistors 1405, 1410, 1415, 1420, 1425, and 1430. NMOS transistors 1405 and 1430 may each have a length of about 2 μm and a width of about 39 μm. The NMOS transistors 1410 and 1425 may each have a length of about 2 μm and a width of about 15 μm. The NMOS transistors 1415 and 1420 may have a length of about 2 μm and a width of about 6 μm. The voltage-level shifter 1400 may also include PMOS transistors 1435, 1440, and 1445. The PMOS transistor 1435 may have a length of 2 μm and a width of 15 μm. The PMOS transistor 1440 may have a length of 2 μm and a width of 24 μm. The PMOS transistor 1445 may have a length of about 2 μm and a width of about 3 μm. The voltage level shifter may include one or more capacitors such as capacitors 1450, 1455, and 1460. The capacitors 1450 and 1455 may have a capacitance of about 4 pF. The capacitor 1460 may have a capacitance of about 100 fF.

A second portion of the level shifter is shown in FIG. 14B. The level shifter 1400 may include NMOS transistors 1465 and 1470 which may each have a length of about 2 μm and a width of about 21 μm. The level shifter 1400 may include PMOS transistors 1475 and 1480 which may each a length of about 2 μm and a width of about 9 μm. The NMOS transistors 1465 and 1470 and the PMOS transistors 1475 and 1480 may be high-voltage transistors as discussed above.

The level shifter 1400 may receive VDD, VDDHV, and ground signals. The level shifter 1400 may also receive clock (CLK) and inverted clock (\overline{CLK}) signals, one or both of which may be buffered.

The high-voltage transistors, and circuits using the high-voltage transistors, may be used in a high-temperature or radioactive environments. Such environments may include well-drilling, power generation, space applications, environments within or near a jet engine, or environments within or near an internal-combustion engine. The term well-drilling is not meant to be limited to oil-well drilling and may include, for example, any applications subject to the high temperature downhole environment: logging applications, workover applications, long term production monitoring applications, downhole controls, fluid extraction applications, measurement or logging while drilling applications.

Therefore, the present invention is well-adapted to carry out the objects and attain the ends and advantages mentioned as well as those which are inherent therein. While the invention has been depicted, described, and is defined by reference to exemplary embodiments of the invention, such a reference does not imply a limitation on the invention, and no such limitation is to be inferred. The invention is capable of considerable modification, alternation, and equivalents in form and function, as will occur to those ordinarily skilled in the pertinent arts and having the benefit of this disclosure. The depicted and described embodiments of the invention are exemplary only, and are not exhaustive of the scope of the invention. Consequently, the invention is intended to be limited only by the spirit and scope of the appended claims, giving full cognizance to equivalents in all respects.

1. A high-voltage transistor comprising:
a substrate comprising sapphire; and
an active layer disposed on the substrate, the active layer comprising:
a drain region;
a source region;
a channel region; and
a lightly-doped drain region between the channel region and the drain region.

2. The high-voltage transistor of claim 1, where the channel region has a length L, the active layer has a thickness tSi, and L/tsi is greater than 5.

3. The high-voltage transistor of claim 1, where the channel region has a length L, the active layer has a thickness tSi, and L/tsi is greater than 7.

4. The high-voltage transistor of claim 1, where the channel region has a length L, the active layer has a thickness tSi, and L/tsi is between 7 and 30.

5. The high-voltage transistor of claim 1, where the channel region has a length L, the active layer has a thickness tSi, and L/tsi is between 11.8 and 25.

6. The high-voltage transistor of claim 1, where the channel region has a length L, the active layer has a thickness tSi, and L/tsi is about 17.7.

7. The high-voltage transistor of claim 1, where the high-voltage transistor further comprises:
a oxide layer disposed on the active layer; and
a polysilicon layer disposed on the oxide layer.

8. The high-voltage transistor of claim 7, where the active layer is separated from the polysilicon layer by a thickness TOX.

9. The high-voltage transistor of claim 1, further comprising:
a body layer disposed on the substrate;
a body-tie connecting the source region and the body layer.

10. The high-voltage transistor of claim 1, where the active layer further comprises:
a resistive region between the channel and drain regions.

11. The high-voltage transistor of claim 10, where the resistive region is doped n—.

12. The high-voltage transistor of claim 1, where the high-voltage transistor is for use in one or more of the following environments:
in a power-generation environment;
in a well-drilling environment;
in space;
within or near a jet engine; or
within or near an internal-combustion engine.

13. A high-voltage transistor comprising:
a substrate comprising diamond; and
an active layer disposed on the substrate, the active layer comprising:
a drain region;
a source region;
a channel region; and
a lightly-doped drain region between the channel region and the drain region.

14. The high-voltage transistor of claim 13, where the channel region has a length L, the active layer has a thickness tSi, and L/tsi is greater than 5.

15. The high-voltage transistor of claim 13, where the channel region has a length L, the active layer has a thickness tSi, and L/tsi is greater than 7.

16. The high-voltage transistor of claim 13, where the channel region has a length L, the active layer has a thickness tSi, and L/tsi is between 7 and 30.

17. The high-voltage transistor of claim 13, where the channel region has a length L, the active layer has a thickness tSi, and L/tsi is between 11.8 and 25.

18. The high-voltage transistor of claim 13, where the channel region has a length L, the active layer has a thickness tSi, and L/tsi is about 17.7.

19. The high-voltage transistor of claim 13, where the high-voltage transistor further comprises:
a oxide layer disposed on the active layer; and
a polysilicon layer disposed on the oxide layer.

20. The high-voltage transistor of claim 19, where the active layer is separated from the polysilicon layer by a thickness TOX.

21. The high-voltage transistor of claim 13, further comprising:
a body layer disposed on the substrate;
a body-tie connecting the source region and the body layer.

22. The high-voltage transistor of claim 13, where the active layer further comprises:
a resistive region between the channel and drain regions.

23. The high-voltage transistor of claim 22, where the resistive region is doped n—.

24. The high-voltage transistor of claim 13, where the high-voltage transistor is for use in one or more of the following environments:
in a power-generation environment;
in a well-drilling environment;
in space;
within or near a jet engine; or
within or near an internal-combustion engine.

25. A charge pump comprising:
one or more high-voltage transistors comprising:
a substrate comprising sapphire; and
an active layer disposed on the substrate, the active layer comprising:
a drain region;
a source region;
a channel region; and
a lightly-doped drain region between the channel region and the drain region.

26. The charge pump of claim 25, where the channel region has a length L, the active layer has a thickness tSi, and L/tsi is greater than 5.

27. The charge pump of claim 25, where the channel region has a length L, the active layer has a thickness tSi, and L/tsi is greater than 7.

28. The charge pump of claim 25, where the channel region has a length L, the active layer has a thickness tSi, and L/tsi is between 7 and 30.

29. The charge pump of claim 25, where the channel region has a length L, the active layer has a thickness tSi, and L/tsi is between 11.8 and 25.

30. The charge pump of claim 25, where the channel region has a length L, the active layer has a thickness tSi, and L/tsi is about 17.7.

31. The charge pump of claim 25, where the high-voltage transistor further comprises:
a oxide layer disposed on the active layer; and
a polysilicon layer disposed on the oxide layer.

32. The charge pump of claim 31, where the active layer is separated from the polysilicon layer by a thickness TOX.

33. The charge pump of claim 25, further comprising:
a body layer disposed on the substrate;
a body-tie connecting the source region and the body layer.

34. The charge pump of claim 25, where the active layer further comprises:
a resistive region between the channel and drain regions.

35. The charge pump of claim 25, where the resistive region is doped n—.

36. The charge pump of claim 25, further comprising:
one or more diodes coupled to one or more of the high-voltage transistors.

37. The charge pump of claim 25, further comprising:
one or more capacitors coupled to one or more of the high-voltage transistors.

38. The charge pump of claim 25, where the charge pump is for use in one or more of the following environments:
in a power-generation environment;
in a well-drilling environment;
in space;
within or near a jet engine; or
within or near an internal-combustion engine.

39. A charge pump comprising:
one or more high-voltage transistors comprising:
a substrate comprising diamond; and
an active layer disposed on the substrate, the active layer comprising:
a drain region;
a source region;
a channel region; and
a lightly-doped drain region between the channel region and the drain region.

40. The charge pump of claim 39, where the channel region has a length L, the active layer has a thickness tSi, and L/tsi is greater than 5.

41. The charge pump of claim 39, where the channel region has a length L, the active layer has a thickness tSi, and L/tsi is greater than 7.

42. The charge pump of claim 39, where the channel region has a length L, the active layer has a thickness tSi, and L/tsi is between 7 and 30.

43. The charge pump of claim 39, where the channel region has a length L, the active layer has a thickness tSi, and L/tsi is between 11.8 and 25.

44. The charge pump of claim 39, where the channel region has a length L, the active layer has a thickness tSi, and L/tsi is about 17.7.

45. The charge pump of claim 39, where the high-voltage transistor further comprises:
a oxide layer disposed on the active layer; and
a polysilicon layer disposed on the oxide layer.

46. The charge pump of claim 45, where the active layer is separated from the polysilicon layer by a thickness TOX.

47. The charge pump of claim 39, further comprising:
a body layer disposed on the substrate;
a body-tie connecting the source region and the body layer.

48. The charge pump of claim 39, where the active layer further comprises:
a resistive region between the channel and drain regions.

49. The charge pump of claim 48, where the resistive region is doped n−-.

50. The charge pump of claim 39, further comprising:
one or more diodes coupled to one or more of the high-voltage transistors.

51. The charge pump of claim 39, further comprising:
one or more capacitors coupled to one or more of the high-voltage transistors.

52. The charge pump of claim 39, where the charge pump is for use in one or more of the following environments:
in a power-generation environment;
in a well-drilling environment;
in space;
within or near a jet engine; or
within or near an internal-combustion engine.

53. A voltage level shifter comprising:
one or more high-voltage transistors comprising:
a substrate comprising sapphire; and
an active layer disposed on the substrate, the active layer comprising:
a drain region;
a source region;
a channel region; and
a lightly-doped drain region between the channel region and the drain region.

54. The voltage level shifter of claim 53, where the channel region has a length L, the active layer has a thickness tSi, and L/tsi is greater than 5.

55. The voltage level shifter of claim 53, where the channel region has a length L, the active layer has a thickness tSi, and L/tsi is greater than 7.

56. The voltage level shifter of claim 53, where the channel region has a length L, the active layer has a thickness tSi, and L/tsi is between 7 and 30.

57. The voltage level shifter of claim 53, where the channel region has a length L, the active layer has a thickness tSi, and L/tsi is between 11.8 and 25.

58. The voltage level shifter of claim 53, where the channel region has a length L, the active layer has a thickness tSi, and L/tsi is about 17.7.

59. The voltage level shifter of claim 53, where the high-voltage transistor further comprises:
a oxide layer disposed on the active layer; and
a polysilicon layer disposed on the oxide layer.

60. The voltage level shifter of claim 59, where the active layer is separated from the polysilicon layer by a thickness TOX.

61. The voltage level shifter of claim 53, further comprising:
a body layer disposed on the substrate;
a body-tie connecting the source region and the body layer.

62. The voltage level shifter of claim 53, where the active layer further comprises:
a resistive region between the channel and drain regions.

63. The voltage level shifter of claim 62, where the resistive region is doped n—.

64. The voltage level shifter of claim 53, further comprising:
one or more diodes coupled to one or more of the high-voltage transistors.

65. The voltage level shifter of claim 53, further comprising:
one or more capacitors coupled to one or more of the high-voltage transistors.

66. The voltage level shifter of claim 53, where the voltage level shifter is for use in one or more of the following environments:
in a power-generation environment;
in a well-drilling environment;
in space;
within or near a jet engine; or
within or near an internal-combustion engine.

67. A voltage level shifter comprising:
one or more high-voltage transistors comprising:
a substrate comprising sapphire; and
an active layer disposed on the substrate, the active layer comprising:
a drain region;
a source region;
a channel region; and
a lightly-doped drain region between the channel region and the drain region.

68. The voltage level shifter of claim 67, where the channel region has a length L, the active layer has a thickness tSi, and L/tsi is greater than 5.

69. The voltage level shifter of claim 67, where the channel region has a length L, the active layer has a thickness tSi, and L/tsi is greater than 7.

70. The voltage level shifter of claim 67, where the channel region has a length L, the active layer has a thickness tSi, and L/tsi is between 7 and 30.

71. The voltage level shifter of claim 67, where the channel region has a length L, the active layer has a thickness tSi, and L/tsi is between 11.8 and 25.

72. The voltage level shifter of claim 67, where the channel region has a length L, the active layer has a thickness tSi, and L/tsi is about 17.7.

73. The voltage level shifter of claim 67, where the high-voltage transistor further comprises:
a oxide layer disposed on the active layer; and
a polysilicon layer disposed on the oxide layer.

74. The voltage level shifter of claim 73, where the active layer is separated from the polysilicon layer by a thickness TOX.

75. The voltage level shifter of claim 67, further comprising:
a body layer disposed on the substrate;
a body-tie connecting the source region and the body layer.

76. The voltage level shifter of claim 67, where the active layer further comprises:
a resistive region between the channel and drain regions.

77. The voltage level shifter of claim 67, where the resistive region is doped n—.

78. The voltage level shifter of claim 67, further comprising:
one or more diodes coupled to one or more of the high-voltage transistors.

79. The voltage level shifter of claim 67, further comprising:
one or more capacitors coupled to one or more of the high-voltage transistors.

80. The voltage level shifter of claim 67, where the voltage level shifter is for use in one or more of the following environments:
in a power-generation environment;
in a well-drilling environment;
in space;
within or near a jet engine; or
within or near an internal-combustion engine.

81. A method of fabricating a high-voltage transistor, comprising:
providing a substrate comprising sapphire;
disposing an active layer on the substrate, the active layer having a length L and a thickness tSi;
doping a source region in the active layer;
doping a drain region in the active layer;
doping a channel region in the active layer; and
doping a lightly-doped drain region in the active layer between the channel region and the drain region.

82. The method of claim 81, where the channel region has a length L and the active layer has a thickness tSi, and where doping a channel region in the active layer comprises:
limiting L/tSi to more than 7.

83. The method of claim 81, where the channel region has a length L and the active layer has a thickness tSi, and where doping a channel region in the active layer comprises:
limiting L/tSi to between 7 and 30.

84. The method of claim 81, further comprising:
disposing an oxide layer on the active layer.

85. The method of claim 84, further comprising:
disposing a poly layer on the oxide layer.

86. The method of claim 81, where the channel region has a length L and the active layer has a thickness tSi, and where doping a channel region in the active layer comprises:
limiting L/tSi to between 11.8 and 25.

87. The method of claim 81, where the channel region has a length L and the active layer has a thickness tSi, and where doping a channel region in the active layer comprises:
limiting L/tSi to about 17.7.

88. The method of claim 81, where the semiconductor device is for use in one or more of the following environments:
in a power-generation environment;
in a well-drilling environment;
in space;
within or near a jet engine; or
within or near an internal-combustion engine.
